(19) United States
(12) Patent Application Publication
(10) Pub. No.: US 2026/0313757 A1
(43) Pub. Date: Oct. 8, 2026

(54) HEATER DEVICE, HEATING UNIT, AND METHOD FOR MANUFACTURING HEATER DEVICE

(71) Applicants: NICHIAS Corporation, Tokyo (JP); Thermos Corporation, Yamatokoriyama-shi, Nara (JP)

(72) Inventors: Akira SASAKI, Tokyo (JP); Keiichi FUKUDA, Tokyo (JP); Daisaku SEKI, Tokyo (JP); Kenji IIDA, Tokyo (JP); Susumu TAGUCHI, Nara (JP)

(21) Appl. No.: 19/156,894

(22) PCT Filed: Feb. 13, 2024
(86) PCT No.: PCT/JP2024/004755

§ 371 Date: Aug. 15, 2025

(30) Foreign Application Priority Data
Feb. 24, 2023 (JP) 2023-027155

(51) Int. Cl. H05B 3/44; H05B 1/02

(52) U.S. Cl. CPC H05B 3/44; H05B 1/0213; H05B 2203/017

(57) ABSTRACT

An object is to determine, with respect to a heated object, the position of a switching device that switches between an electrically conductive state and an electrically non-conductive state of a heat generation body. A heater device arranged along an external surface of the heated object includes: the heat generation body that generates heat while being supplied with power; the switching device that switches between the electrically conductive state and the electrically non-conductive state of the heat generation body, in accordance with a temperature of the heated object; and a thermal insulation member positioned between an inner skin member and an outer skin member. The thermal insulation member has an accommodation part forming a space for accommodating the switching device therein.

### TECHNICAL FIELD

The present invention relates to a heater device or a heating unit that heats a heated object and to a method for manufacturing the heater device.

### BACKGROUND ART

A heater device disclosed in Patent Literature 1 is provided with a bimetal-type thermostat that blocks electrical conductivity when a first temperature is reached and restores the electrical conductivity when the temperature has dropped to reach a second temperature. Further, the restoration temperature of the bimetal-type thermostat is equal to or lower than 0° C. The heater device may be used as a mantle heater for heating a pipe.

### CITATION LIST

### Patent Literature

Patent Literature 1: Japanese Patent Laid-Open No. 2006-286316

### SUMMARY OF INVENTION

### Technical Problem

Although Patent Literature 1 discloses providing the bimetal-type thermostat inside the heater device, no specific positioning structure of the bimetal-type thermostat is disclosed.

When it is desirable to operate a thermostat in accordance with temperature of a pipe, the thermostat needs to be kept in contact with the pipe. If the position of the thermostat is displaced within the heater device, there is a possibility that the thermostat may not operate properly because heat of the pipe may not easily be transferred to the thermostat due to the thermostat being positioned apart from the pipe.

### Solution to Problem

A first invention of the present disclosure relates to a heater device arranged along an external surface of a heated object, including: a heat generation body that generates heat while being supplied with power; a switching device that switches between an electrically conductive state and an electrically non-conductive state of the heat generation body, in accordance with a temperature of the heated object; and a thermal insulation member positioned between an inner skin member and an outer skin member. The thermal insulation member has an accommodation part forming a space for accommodating the switching device therein.

The accommodation part may be a through hole that penetrates the thermal insulation member or may be a recessed part that opens toward the external surface of the heated object. When the heat generation body includes a heater wire, the heater wire may be arranged according to a prescribed arrangement pattern on the surface of the thermal insulation member, while a part of the heater wire may be arranged along the accommodation part in a position apart from the accommodation part by a prescribed distance.

The heat generation body may be structured with a heater wire and a supporting sheet to which the heater wire is fixed. An opening part to be penetrated by the switching device may be formed in the supporting sheet; and a flange part provided for the switching device may be attached to the supporting sheet. In this situation, an inorganic fiber sheet may be used as the supporting sheet; and an edge of the opening part of the supporting sheet may be sewn by using a reinforcement thread.

The heater device may be provided with a temperature sensor for detecting the temperature of the heated object. The temperature sensor may be structured with a detection unit that detects the temperature of the heated object and a wiring part extending from the detection unit; and a tip end part of the temperature sensor including the detection unit may be exposed to the heated object. In this situation, the tip end part of the temperature sensor may be arranged in a position that does not overlap with the heater wire of the heat generation body, as viewed in the lamination direction of an inner skin member and an outer skin member. With this configuration, heat from the heater wire is prevented from being transferred to the tip end part (the detection unit, in particular) of the temperature sensor, which makes it easier for the detection unit to detect the temperature of the heated object.

The wiring part of the temperature sensor may be arranged along a bypassing path within lamination planes of the inner skin member and the outer skin members. The bypassing path is a path that bypasses the shortest path connecting together a starting end and a terminating end which are positioned on the lamination planes. As a result of arranging the wiring part along the bypassing path, it is possible to prevent the wiring part from being displaced, even when tensile force is applied to the wiring part.

A second invention of the present disclosure relates to a heating unit arranged along an external surface of a heated object, including: a heat generation body that generates heat while being supplied with power; a switching device that switches between an electrically conductive state and an electrically non-conductive state of the heat generation body, in accordance with a temperature of the heated object; and a thermal insulation member positioned between an inner skin member and an outer skin member. The thermal insulation member has an accommodation part forming a space for accommodating the switching device therein.

A third invention of the present disclosure relates to a method for manufacturing a heater device arranged along an external surface of a heated object.

In the present example, the heater device includes: a heat generation body that generates heat while being supplied with power; a switching device that switches between an electrically conductive state and an electrically non-conductive state of the heat generation body, in accordance with a temperature of the heated object; and a thermal insulation member positioned between an inner skin member and an outer skin member.

According to the method for manufacturing the heater device, the thermal insulation member has formed therewith an accommodation part having a prescribed space, so that the switching device is accommodated in the accommodation part.

In the first to the third inventions of the present disclosure, a thermostat may be used as the switching device.

### Advantageous Effects of Invention

According to the present invention, it is possible, in the heater device, to determine the position of the switching device because the accommodation part of the thermal insulation member accommodates the switching device therein. As a result, it is possible to keep the switching device in contact with the heated object without any displacement, and it is therefore possible to have the heat of the heated object efficiently transferred to the switching device. Further, it is possible to cause the switching device to operate appropriately in accordance with the temperature of the heated object.

### BRIEF DESCRIPTION OF DRAWINGS

FIG. 1 is a perspective view showing a structure of a heater device attached to a pipe.

FIG. 2 is a side view of a thermostat.

FIG. 3 is a bottom view of the thermostat.

FIG. 4 is a cross-sectional view showing a structure in which the thermostat is embedded in a heater device.

FIG. 5 is a schematic drawing of a thermal insulation member, showing a part accommodating therein the thermostat.

FIG. 6 is a drawing for explaining a structure for fixing the thermostat onto a sheet and a positional relationship between the thermostat and a heater wire.

FIG. 7 is another drawing for explaining the structure for fixing the thermostat onto the sheet and the positional relationship between the thermostat and the heater wire.

FIG. 8 is a drawing for explaining a positional relationship between a tip end part of a temperature sensor and the heater wire.

FIG. 9 is a drawing for explaining a bypassing path used at the time of arranging a wiring part of the temperature sensor.

### DESCRIPTION OF EMBODIMENTS

### First Embodiment

A heater device according to a first embodiment of the present invention is to be attached to the outer circumferential surface of a pipe to heat the inside of the pipe. For example, in order to prevent coagulation and precipitation of by-products and exhaust gas inside of the pipe for gas to flow, it is possible to heat the inside of the pipe. Meanwhile, the heater device of the present embodiment is not limited to heating a pipe and is sufficient as long as it is possible to apply heat to a heated object subject to a heating process.

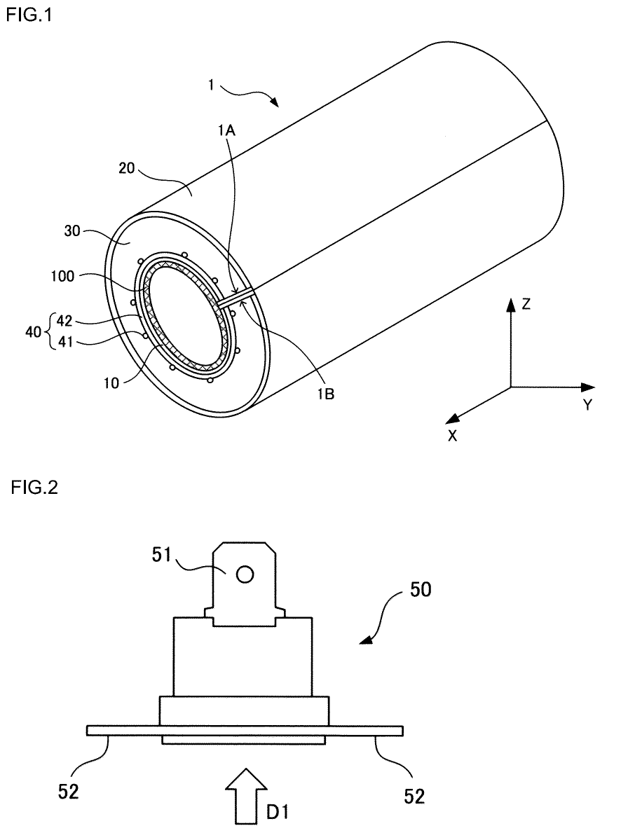

FIG. 1 is a perspective view showing a configuration of a heater device 1 attached to a pipe 100 having a circular cylindrical shape. In FIG. 1, the X-axis, the Y-axis, and the Z-axis are axes orthogonal to one another, while the pipe 100 extends in the X-axis direction. In the present embodiment, an example will be explained in which the heater device 1 is attached to the pipe 100 extending in the X-axis direction; however, it is also possible to attach the heater device 1 to the pipe 100 that is bent. In that situation, it is suggested that the heater device 1 be formed in a bent shape so as to be fitted along a bent part of the pipe 100.

The heater device 1 is arranged along the circumferential direction of the pipe 100 and includes a pair of abutment parts 1A and 1B caused to abut against each other in the circumferential direction of the pipe 100. It is possible to cover the outer circumferential surface of the pipe 100 with the heater device 1, by bending the heater device 1 along the outer circumferential surface of the pipe 100 and causing the pair of abutment parts 1A and 1B to abut against each other.

The heater device 1 includes: an inner skin member 10 that is in contact with the outer circumferential surface of the pipe 100; an outer skin member 20 structuring the external surface of the heater device 1; and a thermal insulation member 30 positioned between the inner skin member 10 and the outer skin member 20.

The inner skin member 10 and the outer skin member 20 may each be formed by using resin and may each have a porous structure. The inner skin member 10 and the outer skin member 20 may be formed by using mutually the same type of resin or may be formed by using mutually-different types of resin.

Possible examples of the resin used for forming the inner skin member 10 and the outer skin member 20 include: polytetrafluoroethylene (PTFE), perfluoroalkoxy alkane (PFA), fluorinated ethylene propylene (FEP), polychlorotrifluoroethylene (PCTFE), ethylene tetrafluoroethylene (ETFE), ethylene-chlorotrifluoroethylene (ECTFE), and polyvinylidene fluoride (PVDF). Further, it is also possible to use thermoplastic resin such as polyamide, polycarbonate, polyacetal, polybutylene terephthalate, modified polyphenylene ether, polyphenylene sulfide, polysulfone, polyethersulfone, polyarylate, polyether ether ketone, polyphthalamide, polyimide, polyetherimide, or polymethylpentene. Furthermore, it is also possible to use fluororesin fiber cloth (woven cloth) obtained by weaving fibers of any of the aforementioned fluorine-based resins; inorganic fiber cloth (woven cloth) including inorganic fibers such as glass fibers, silica fibers, alumina fibers, or silica alumina fibers; fluororesin-coated inorganic fiber cloth obtained by coating inorganic fiber cloth with a fluorine-based resin; or silicone resin-coated inorganic fiber cloth obtained by coating inorganic fiber cloth with a silicone resin.

Positioned between the inner skin member 10 and the thermal insulation member 30 is a heat generation body 40. The heat generation body 40 includes: a heater wire 41 that generates heat while being supplied with power; and a supporting sheet 42 to which the heater wire 41 is sewn. The heater wire 41 may be arranged according to a prescribed arrangement pattern so as to be able to uniformly heat the entire region of the pipe 100 covered by the heater device 1. An end part of the heater wire 41 is connected to a cable (not shown), while the cable is drawn to the outside of the heater device 1 and is connected to a power source (not shown) provided outside the heater device 1. By having electricity supplied from the power source to the heater wire 41, it is possible to cause the heater wire 41 to generate the heat.

The supporting sheet 42 is a sheet-like member formed by using inorganic fibers such as glass fibers, ceramic fibers, or silica fibers. The heat generation body 40 may be arranged so that the supporting sheet 42 is in contact with the inner skin member 10, while the heater wire 41 is positioned between the supporting sheet 42 and the thermal insulation member 30. As a result, the heater wire 41 is arranged on the surface of the thermal insulation member 30.

In this situation, the supporting sheet 42 may be structured as a single layer or may be structured as a laminated body obtained by laminating a plurality of layers. In that situation, the plurality of layers structuring the laminated body may be formed by using mutually the same type of material or may be formed by using mutually-different types of materials. It is also possible to structure the supporting sheet 42 by laminating a plurality of layers formed by using mutually the same type of material, together with at least one layer formed by using another type of material.

The thermal insulation member 30 may be formed, for example, by using inorganic fibers or organic fibers and may preferably be formed by using a non-flammable or fire-retardant material. Examples of the inorganic fibers that can be used include glass fibers, ceramic fibers, and silica fibers. In this situation, the inorganic fibers may have needle processing applied thereto and may be shaped by using an inorganic binder such as colloidal silica, alumina sol, or silicic acid. Further, examples of the organic fibers that can be used include fibers formed with aramid, polyamide, or polyimide.

The thermal insulation member 30 may be in contact with the internal surface of the outer skin member 20, but it is also acceptable to provide a sheet (not shown) between the thermal insulation member 30 and the outer skin member 20. The sheet may be formed by using the same or a similar material as that of the supporting sheet 42 described above and may be structured as a single layer or a plurality of layers.

A temperature sensor (not shown) for detecting temperature of the pipe 100 may be attached to an arbitrary location of the heater device 1. Further, by controlling the electrical conductivity of the heater wire 41 on the basis of the temperature detected by the temperature sensor, it is possible to maintain the temperature of the pipe 100 at a desired level. In this situation, the quantity of the temperature sensors may be determined as appropriate.

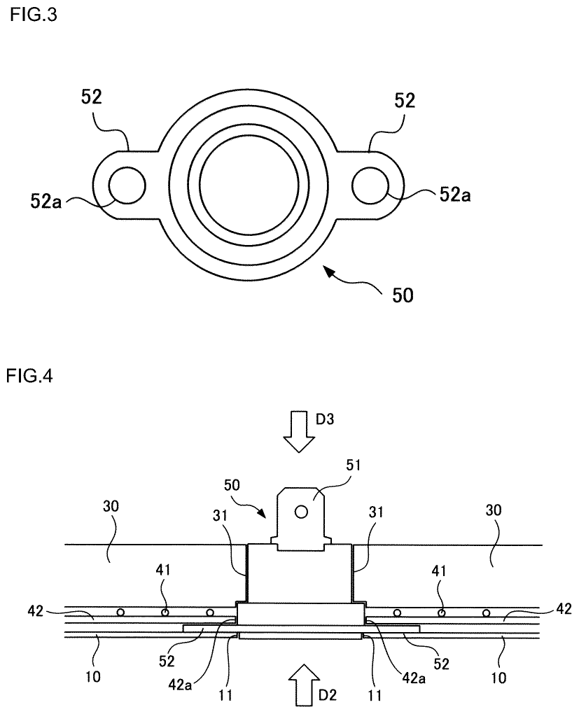

The heater device 1 is provided with a thermostat (switching device) 50 shown in FIG. 2 and FIG. 3.

The thermostat 50 is a thermostat of a bimetal type and is configured to switch between an electrically conductive state and an electrically non-conductive state of the heater wire 41 in accordance with the temperature of the pipe 100. The thermostat 50 is positioned so as to be in contact with the outer circumferential surface of the pipe 100 so that heat of the pipe 100 is transferred to the thermostat 50. With this configuration, it is possible to cause the thermostat 50 to operate in accordance with the temperature of the pipe 100.

Further, although the thermostat 50 is in direct contact with the outer circumferential surface of the pipe 100 in the present embodiment, possible embodiments are not limited to this example, and it is also acceptable to have another member interposed between the thermostat 50 and the pipe 100. In that situation also, it is sufficient as long as the heat of the pipe 100 is transferred to the thermostat 50 via the interposed member. Further, it is also acceptable to use, other than the thermostat 50, an element capable of switching between the electrically conductive state and the electrically non-conductive state of the heater wire 41, in accordance with temperature of a heated object (e.g., the pipe 100).

A structure (an example) of the thermostat 50 will be explained, with reference to FIG. 2 and FIG. 3.

FIG. 2 is a side view of the thermostat 50, whereas FIG. 3 is a drawing (a bottom view) of the thermostat 50 as viewed in the direction of the arrow D1 in FIG. 2. It should be noted that possible structures of the thermostat 50 are not limited to the structure shown in FIG. 2 and FIG. 3.

A bimetal (not shown), which is provided inside the thermostat 50, deforms depending on temperature to turn a switch on or off. The heater wire 41 is allowed to be electrically conductive when the switch is in the ON state, whereas the electrical conductivity of the heater wire 41 is blocked when the switch is in the OFF state.

The thermostat 50 includes a pair of terminals 51 connected to the heater wire 41 and a pair of flanges 52 for fixing the thermostat 50. The pair of terminals 51 are connected to the switch turned on/off by the bimetal described above. As shown in FIG. 3, the flanges 52 each have an opening part 52a formed therein, so that it is possible to fix the thermostat 50 onto the supporting sheet 42, by having a thread sewn onto the supporting sheet 42, while putting the thread through the opening parts 52a.

In the present embodiment, the thermostat 50 is fixed onto the supporting sheet 42 by using the thread; however, possible embodiments are not limited to this example. In other words, it is sufficient as long as it is possible to fix the thermostat 50 to the supporting sheet 42. For example, it is acceptable to fix the flanges 52 of the thermostat 50 to the supporting sheet 42 by using an adhesive agent. Further, even when the thermostat 50 is not provided with the flanges 52, it is possible to fix the thermostat 50 to the supporting sheet 42, by using publicly-known fixation means (e.g., an adhesive agent).

FIG. 4 is a cross-sectional view showing a state in which the thermostat 50 is fixed to the supporting sheet 42. The supporting sheet 42 has formed therein an opening part 42a to be penetrated by the thermostat 50.

The inner skin member 10 also has formed therein an opening part 11 to be penetrated by the thermostat 50.

With this configuration, it is possible to bring the thermostat 50 into contact with the outer circumferential surface of the pipe 100.

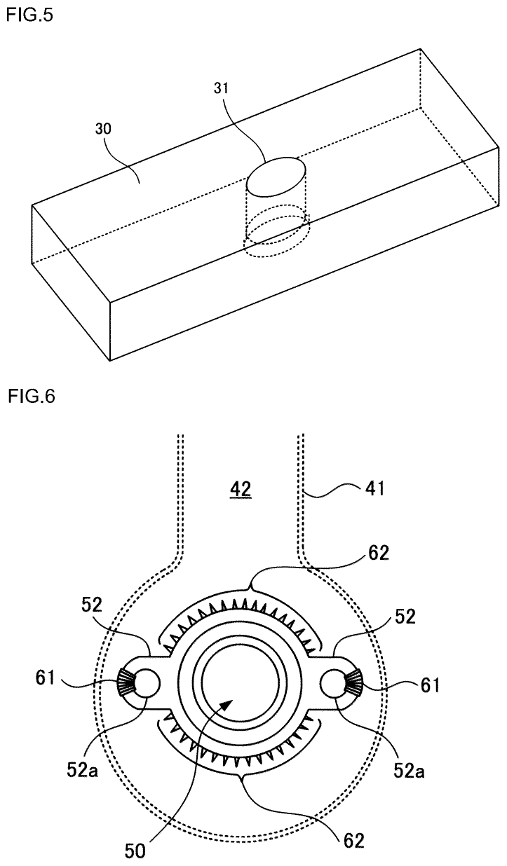

The thermal insulation member 30 is provided with an accommodation part 31 to accommodate a part of the thermostat 50 therein. As shown in FIG. 5, the accommodation part 31 is a through hole penetrating the thermal insulation member 30 and is formed to have a shape fitted along the exterior shape of the thermostat 50. In this situation, the accommodation part 31 does not need to be strictly fitted along the exterior shape of the thermostat 50. It is sufficient as long as at least a part of the accommodation part 31 is in contact with the external surface of the thermostat 50, so as to be able to determine the position of the thermostat 50.

As shown in FIG. 4, the flanges 52 of the thermostat 50 are positioned between the supporting sheet 42 and the inner skin member 10 and, as explained above, are sewn onto the supporting sheet 42. It is possible to determine the position of the thermostat 50, also by sewing the flanges 52 onto the supporting sheet 42.

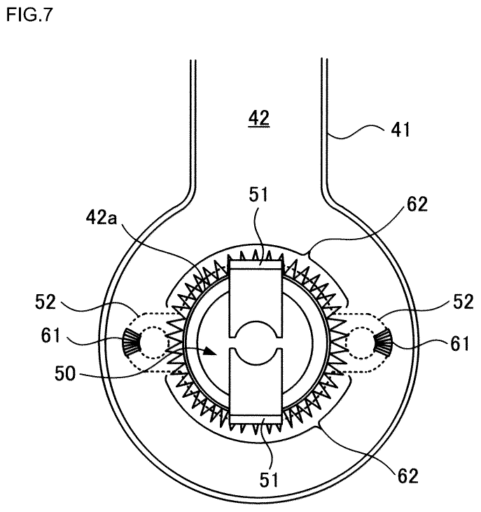

FIG. 6 shows a state (an example) in which the flanges 52 are sewn onto the supporting sheet 42 and is a drawing of the thermostat 50 as viewed in the direction of the arrow D2 in FIG. 4. The inner skin member 10 shown in FIG. 4 is omitted from FIG. 6. Further, FIG. 7 is a drawing of the thermostat 50 as viewed in the direction of the arrow D3 in FIG. 4. The thermal insulation member 30 is omitted from FIG. 7.

As shown in FIG. 6, a thread 61 is put through the opening parts 52a of the flanges 52, so as to have the thread 61 sewn onto the supporting sheet 42. In addition, a reinforcement thread 62 is sewn onto the supporting sheet 42 along the edge of the opening part 42a, so as to ensure strength of the opening part 42a.

As shown in FIG. 7, the heater wire 41 is arranged with the supporting sheet 42 so as to avoid the region where the thermostat 50 is provided. More specifically, the heater wire 41 is arranged along the opening part 42a in a certain position apart from the opening part 42a of the supporting sheet 42 by a prescribed distance. For example, it is possible to fix the heater wire 41 onto the supporting sheet 42, by having a thread (not shown) sewn onto the supporting sheet 42 in such a manner that the heater wire 41 is pressed onto the supporting sheet 42 by the thread.

By arranging the heater wire 41 as described above, it is possible to ensure that the heat generated from the heater wire 41 is not easily transferred to the thermostat 50, and it is therefore possible to prevent malfunctioning of the thermostat 50 that may be caused by the heat occurring from the heater wire 41.

Further, in a certain region of the supporting sheet 42 where the thermostat 50 is not positioned, it is possible to arrange the heater wire 41 according to a prescribed arrangement pattern, so that the heat generated from the heater wire 41 is easily transferred to the entirety of the pipe 100. For example, on the surface of the supporting sheet 42, it is possible to arrange the heater wire 41 so that the heater wire 41 is folded back and forth so as to form rows positioned at prescribed intervals. In this situation, in an attempt to cause the heat of the heater wire 41 to be efficiently transferred to the entirety of the pipe 100, there is a tendency that the abovementioned intervals between the rows of the heater wire 41 become smaller than the outside diameter of the thermostat 50. In that situation, to avoid interference between the heater wire 41 and the thermostat 50, significance lies in that the heater wire 41 is arranged along the opening part 42a as described above.

According to the present embodiment, the accommodation part 31 of the thermal insulation member 30 is formed so as to be fitted along the exterior shape of the thermostat 50 and to accommodate the thermostat 50 therein and is thus able to determine the position of the thermostat 50 in the heater device 1. With this configuration, it is possible to keep the thermostat 50 into contact with the pipe 100 without the displacement, and it is therefore possible to cause the heat of the pipe 100 to be efficiently transferred to the thermostat 50. Further, it is possible to cause the thermostat 50 to operate appropriately, in accordance with the temperature of the pipe 100.

Further, although the accommodation part 31 penetrates the thermal insulation member 30 in the present embodiment, possible embodiments are not limited to this example. More specifically, the accommodation part 31 may be a recessed part that opens toward the pipe 100, without penetrating the thermal insulation member 30. The lateral face of the recessed part is formed to have a shape fitted along an outer lateral face of the thermostat 50. Even when the thermostat 50 is accommodated in such a recessed part, it is possible to achieve the advantageous effects of the present embodiment described above. When the thermostat 50 is accommodated in such a recessed part, because the terminals 51 of the thermostat 50 are positioned on the bottom face side of the recessed part, it is acceptable to form, in the thermal insulation member 30, a passage for putting through the heater wire 41 connected to the terminals 51.

### Second Embodiment

Next, a second embodiment of the present invention will be explained. In the following sections, some of the members that have the same functions as those of the members explained in the first embodiment will be referred to by using the same reference characters, and detailed explanations thereof will be omitted.

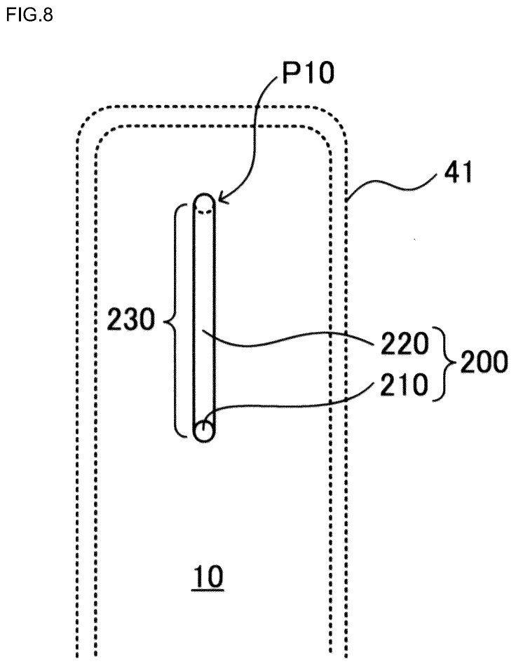

The present embodiment relates to a positional arrangement of a temperature sensor for detecting temperature of the pipe 100. In the present example, a thermocouple may be used as the temperature sensor. In the following sections, the positional arrangement of the temperature sensor will be explained, with reference to FIG. 8.

FIG. 8 is an unfolded view of the inner skin member 10 and illustrates the inner skin member 10 as viewed from the pipe 100 side, showing a partial region of the inner skin member 10. As explained in the first embodiment, the heat generation body 40 is laminated over the inner skin member 10. FIG. 8 illustrates a positional relationship observed when a temperature sensor 200 and the heater wire 41 are viewed in the lamination direction (the direction orthogonal to the drawing page of FIG. 8) of the inner skin member 10 and the heat generation body 40.

The temperature sensor 200 includes a detection unit 210 that detects temperature of the pipe 100 and a wiring part 220 extending from the detection unit 210. A tip end part 230 of the temperature sensor 200 including the detection unit 210 is exposed to the external surface of the pipe 100, in order to detect the temperature of the pipe 100. Further, the tip end part 230 is arranged along a surface (the surface in contact with the pipe 100) of the inner skin member 10 and is fixed to the inner skin member 10 by using a thread (not shown) or the like. The wiring part 220 is bent at a base end position P10 of the tip end part 230 and extends away from the viewer of the drawing page of FIG. 8. In other words, the wiring part 220, except for the tip end part 230, extends to the outside of the heater device 1 so as to be connected to a device provided outside the heater device 1.

As observed in FIG. 8, the tip end part 230 of the temperature sensor 200 is arranged in a position that does not overlap with the heater wire 41. More specifically, the tip end part 230 is arranged along the extending direction (the up-and-down direction in FIG. 8) of the heater wire 41, so as to be positioned between two rows of the heater wire 41 arranged while being folded back and forth. Further, the tip end part 230 is arranged in a position that is also distant from a folded part of the heater wire 41.

According to the present embodiment, because the tip end part 230 (including the detection unit 210) of the temperature sensor 200 is arranged in the position that does not overlap with the heater wire 41 as viewed in the lamination direction of the inner skin member 10 and the heat generation body 40, it is possible to prevent the heat of the heater wire 41 from being transferred to the tip end part 230 of the temperature sensor 200. With this configuration, the detection unit 210 of the temperature sensor 200 is able to detect the temperature of the pipe 100, without being impacted by the heat of the heater wire 41.

Although the tip end part 230 of the temperature sensor 200 is arranged along the extending direction of the heater wire 41 in the present embodiment, possible embodiments are not limited to this example. In other words, it is sufficient as long as the heater wire 41 and the tip end part 230 are arranged so that the heater wire 41 and the tip end part 230 of the temperature sensor 200 do not overlap with each other as viewed in the lamination direction of the inner skin member 10 and the heat generation body 40. For example, when the tip end part 230 is positioned between two rows of the heater wire 41 arranged next to each other in a certain direction, there is no possibility that the heater wire 41 and the tip end part 230 overlap with each other. In that situation, the posture with which the tip end part 230 is arranged is not limited to a posture arranged along the extending direction of the heater wire 41 and may be a posture arranged along a direction different from the extending direction of the heater wire 41.

Further, although the temperature sensor 200 is arranged in the position allowing the exposure to the external surface of the pipe 100 in the present embodiment, possible embodiments are not limited to this example, and it is acceptable to arrange the temperature sensor 200 in any position where the temperature of the pipe 100 can be detected. For example, the temperature sensor 200 may be positioned between the inner skin member 10 and the heat generation body 40 (the supporting sheet 42). This structure is also applicable to the first embodiment described above and a third embodiment to be described below.

### Third Embodiment

Next, the third embodiment of the present invention will be explained. In the following sections, some of the members that have the same functions as those of the members explained in the first embodiment or the second embodiment will be referred to by using the same reference characters, and detailed explanations thereof will be omitted.

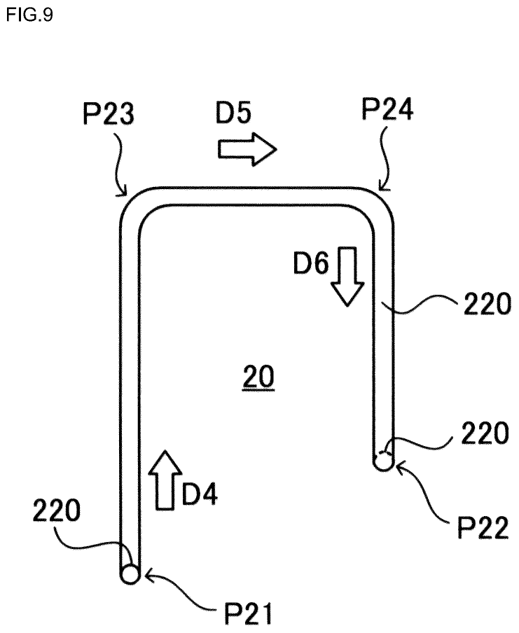

The present embodiment relates to a structure in which the wiring part 220 of the temperature sensor 200 is fixed to the heater device 1, the structure being configured to prevent displacement of the wiring part 220. In the following sections, a positional arrangement of the wiring part 220 will be explained, with reference to FIG. 9. FIG. 9 is an unfolded view of the outer skin member 20, showing the outer skin member 20 as viewed from the thermal insulation member 30 side. FIG. 9 shows a partial region of the outer skin member 20.

As shown in FIG. 9, a part of the wiring part 220 is positioned between the outer skin member 20 and the thermal insulation member 30, while being arranged along the internal surface (the surface in contact with the thermal insulation member 30) of the outer skin member 20. The wiring part 220 is fixed to the outer skin member 20 by using fixation means (not shown) such as a thread or an adhesive agent. Alternatively, it is also acceptable to fix the wiring part 220 onto the thermal insulation member 30, instead of onto the outer skin member 20.

At a first bending position P21 of the wiring part 220 shown in FIG. 9, the wiring part 220 is bent so as to extend toward the viewer of the drawing page, while the detection unit 210 is provided at the tip end of the wiring part 220. In other words, the wiring part 220 extending toward the viewer of the drawing page from the first bending position P21 penetrates the thermal insulation member 30 so as to extend as far as the internal surface (the surface in contact with the pipe 100) of the inner skin member 10.

At a second bending position P22 of the wiring part 220 shown in FIG. 9, the wiring part 220 is bent so as to extend away from the viewer of the drawing page and penetrates the outer skin member 20 so as to further extend to the outside of the heater device 1. With this configuration, it is possible to have the wiring part 220 connected to a device provided outside the heater device 1. The second bending position P22 is at a different position from the first bending position P21 on the internal surface of the outer skin member 20.

In the present embodiment, at the time of arranging the wiring part 220 from the first bending position P21 to the second bending position P22, the wiring part 220 is not arranged along the shortest path linearly extending from the first bending position P21 to the second bending position P22, but the wiring part 220 is arranged along a bypassing path that bypasses the shortest path.

More specifically, after the wiring part 220 is arranged along the direction of the arrow D4 from the first bending position P21, the wiring part 220 is bent at a third bending position P23 so that the wiring part 220 is arranged along the direction of the arrow D5. Further, the wiring part 220 is bent at a fourth bending position P24 so that the wiring part 220 is arranged along the direction of the arrow D6, so that the wiring part 220 reaches the second bending position P22. In this situation, at the third bending position P23 and the fourth bending position P24, the wiring part 220 is bent within a plane expanding along the internal surface of the outer skin member 20.

Although the directions of the arrows D4 and D6 are parallel to each other on the bypassing path of the wiring part 220 shown in FIG. 9, the two directions do not necessarily need to be parallel to each other. In addition, although the directions of the arrows D4 and D5 are orthogonal to each other, while the directions of the arrows D5 and D6 are orthogonal to each other, the two directions do not necessarily need to be orthogonal to each other. In other words, it is sufficient as long as the wiring part 220 is arranged along a path (a bypassing path) deviating from the abovementioned shortest path, on the internal surface of the outer skin member 20.

According to the present embodiment, by arranging the wiring part 220 along the bypassing path, it is possible to prevent the wiring part 220 from being displaced when tensile force is applied to the wiring part 220 from the outside of the heater device 1. In other words, when the tensile force is applied to the wiring part 220, the wiring part 220 arranged along the bypassing path is able to resist the tensile force, and it is therefore possible to prevent displacement of the wiring part 220. Further, because it is possible to prevent positional deviation of the detection unit 210 that may be caused by displacement of the wiring part 220, it is possible to carry out the temperature detection by the detection unit 210 in a desired position of the pipe 100.

Although the wiring part 220 arranged along the bypassing path is arranged on the internal surface of the outer skin member 20 (i.e., in the position between the outer skin member 20 and the thermal insulation member 30) in the present embodiment, possible embodiments are not limited to this example. Having the bypassing path of the wiring part 220 formed on the same plane makes it easier to resist the tensile force that may be applied to the wiring part 220. Thus, it is acceptable, for example, to arrange the wiring part 220 along the bypassing path on a boundary plane between the thermal insulation member 30 and the heat generation body 40 or on a boundary plane between the inner skin member 10 and the heat generation body 40. In those situations, the wiring part 220 may be fixed to one of the thermal insulation member 30 and the heat generation body 40 (the supporting sheet 42) or may be fixed to one of the inner skin member 10 and the heat generation body 40 (the supporting sheet 42).

### REFERENCE SIGNS LIST

100: pipe
1: heater device
1A, 1B: abutment part
10: inner skin member
20: outer skin member
30: thermal insulation member
40: heat generation body
41: heater wire
42: supporting sheet
200: temperature sensor
210: detection unit
220: wiring part

1. A heater device arranged along an external surface of a heated object, comprising:
a heat generation body that generates heat while being supplied with power;
a switching device that switches between an electrically conductive state and an electrically non-conductive state of the heat generation body, in accordance with a temperature of the heated object; and
a thermal insulation member positioned between an inner skin member and an outer skin member, wherein
the thermal insulation member has an accommodation part forming a space for accommodating the switching device therein.

2. The heater device according to claim 1, wherein
the accommodation part is a through hole that penetrates the thermal insulation member.

3. The heater device according to claim 1, wherein
the accommodation part is a recessed part that opens toward the external surface of the heated object.

4. The heater device according to claim 1, wherein
the switching device is a thermostat.

5. A heating unit arranged along an external surface of a heated object, comprising:
a heat generation body that generates heat while being supplied with power;
a switching device that switches between an electrically conductive state and an electrically non-conductive state of the heat generation body, in accordance with a temperature of the heated object; and
a thermal insulation member positioned between an inner skin member and an outer skin member, wherein
the thermal insulation member has an accommodation part forming a space for accommodating the switching device therein.

6. A method for manufacturing a heater device arranged along an external surface of a heated object, wherein
the heater device includes:
a heat generation body that generates heat while being supplied with power;
a switching device that switches between an electrically conductive state and an electrically non-conductive state of the heat generation body, in accordance with a temperature of the heated object; and
a thermal insulation member positioned between an inner skin member and an outer skin member, and
the thermal insulation member has formed therewith an accommodation part having a prescribed space, so that the switching device is accommodated in the accommodation part.

7. The heater device according to claim 2, wherein
the switching device is a thermostat.

8. The heater device according to claim 3, wherein
the switching device is a thermostat.
